(19) United States
(12) Patent Application Publication
(10) Pub. No.: US 2021/0217845 A1
(43) Pub. Date: Jul. 15, 2021

(54) SEMICONDUCTOR DEVICE

(71) Applicant: DENSO CORPORATION, Kariya-city (JP)

(72) Inventors: MASANORI MIYATA, Kariya-city (JP); SHUJI YONEDA, Kariya-city (JP); YUKI YAKUSHIGAWA, Toyota-city (JP); MASARU SENOO, Okazaki-city (JP)

(21) Appl. No.: 17/198,807

(22) Filed: Mar. 11, 2021

Related U.S. Application Data
(63) Continuation of application No. PCT/JP2019/033934, filed on Aug. 29, 2019.

(30) Foreign Application Priority Data
Sep. 13, 2018 (JP) 2018-171732

(51) Int. Cl. H01L 29/06; H01L 29/739

(52) U.S. Cl. CPC H01L 29/0638; H01L 29/7397

(57) ABSTRACT

A semiconductor device has a drift layer, a base layer, an emitter region, a gate insulation film, a gate electrode, a collector layer, a field stop layer, a first electrode and a second electrode. The base layer is disposed on the drift layer. The emitter region is disposed on a surface layer portion of the base layer. The gate insulation film is disposed between the drift layer and the emitter layer. The gate electrode is disposed on the gate insulation film. The collector layer is disposed at a portion of the drift layer opposite to the base layer. The field stop layer is disposed between the collector layer and the drift layer. The field stop layer has a higher carrier concentration than the drift layer. The first electrode is electrically connected to the base layer and the emitter region. The second electrode is electrically connected to the collector layer.

### CROSS REFERENCE TO RELATED APPLICATIONS

The present application is a continuation application of International Patent Application No. PCT/JP2019/033934 filed on Aug. 29, 2019, which designated the U.S. and claims the benefit of priority from Japanese Patent Application No. 2018-171732 filed on Sep. 13, 2018. The entire disclosures of all of the above applications are incorporated herein by reference.

### TECHNICAL FIELD

The present disclosures relates to a semiconductor device including an insulated bipolar transistor (hereinafter referred to as “IGBT”).

### BACKGROUND

A semiconductor device including an IGBT element may be used as a switching element adopted for, for example, an inverter.

### SUMMARY

The present disclosure describes a semiconductor device including a drift layer, a base layer, an emitter region, a gate insulating film, a gate electrode, a collector layer, a field stop layer, a first electrode and a second electrode.

### BRIEF DESCRIPTION OF DRAWINGS

Other objects, features and advantages of the present disclosure will become more apparent from the following detailed description made with reference to the accompanying drawings. In the drawings:

FIG. 1 is a cross-sectional view of a semiconductor device according to a first embodiment;

FIG. 2 illustrates the relationship between a depth from the other surface of a semiconductor substrate and a carrier concentration;

FIG. 3 is a timing chart showing an operation of the semiconductor device;

FIG. 4 illustrates an electric field strength of the semiconductor device;

FIG. 5 illustrates a circuit configuration when executing a short-circuit evaluation;

FIG. 6 explains the principle that a peak of the electric field strength occurs at a lower electrode side at a time of having a short-circuit;

FIG. 7 illustrates an electric field strength of the semiconductor device;

FIG. 8 explains a principle that the peak of the electric field strength is less likely to occur at a lower electrode side at a time of having the short-circuit;

FIG. 9A illustrates the relationship between the electric field strength at a lower part of the semiconductor device and a peak-to-peak distance between an FS (field stop) layer and a collector layer;

FIG. 9B illustrates the relationship between the electric field strength at the lower part of the semiconductor device and a peak-to-peak distance between an FS layer and a collector layer;

FIG. 9C illustrates the relationship between the electric field strength at the lower part of the semiconductor device and a peak-to-peak distance between an FS layer and a collector layer;

FIG. 10A illustrates the relationship between the electric field strength at the lower part of the semiconductor device and a peak-to-peak distance between an FS layer and a collector layer;

FIG. 10B illustrates the relationship between the electric field strength at the lower part of the semiconductor device and a peak-to-peak distance between an FS layer and a collector layer;

FIG. 11 illustrates the relationship between a total impurity amount ratio and a peak-to-peak distance between an FS layer and a collector layer;

FIG. 12 illustrates the relationship between the depth as viewed from the other surface of a semiconductor substrate and a carrier concentration in a second embodiment;

FIG. 13 illustrates the relationship between the depth as viewed from the other surface of a semiconductor substrate and a carrier concentration in a third embodiment;

FIG. 14 illustrates the relationship between the depth as viewed from the other surface of a semiconductor substrate and a carrier concentration in a fourth embodiment; and

FIG. 15 illustrates the relationship between the depth as viewed from the other surface of a semiconductor substrate and a carrier concentration in other embodiment.

### DETAILED DESCRIPTION

A semiconductor device may include a drift layer of N⁻ type and a base layer of P type formed on the drift layer. Multiple trenches are provided in the semiconductor device to penetrate through the base layer. A gate insulation film is formed at a wall surface of each trench. A gate electrode is formed at the gate insulation film. An N⁺ type emitter region is formed on a surface layer portion of the base layer to be in contact with the trenches. On the opposite side from the base layer across the drift layer, a P type collector layer is formed. An upper electrode is formed at the semiconductor substrate to be electrically connected to the base layer and the emitter region, and a lower electrode is formed at the semiconductor substrate to be electrically connected to the collector layer.

For improving a withstand voltage in a semiconductor device, an N-type field stop layer (hereinafter referred to as an “FS layer”), which has a higher carrier concentration than a drift layer, is formed on a collector layer. The withstand voltage may also be referred to as a breakdown voltage.

However, in the above-mentioned semiconductor device, the end portion of a depletion layer tends to be farther from the collector layer at a time of short-circuit with the formation of the FS layer. In the semiconductor device, the number of holes injected into the end portion of the depletion layer decreases so that the number of electrons becomes excessive. The peak of electric field strength may be generated at a location closer to the lower electrode. In a situation where the peak of the electric field strength occurs at a location closer to the lower electrode of the semiconductor device, avalanche breakdown may occur in the vicinity of the peak portion to cause the breakdown of the semiconductor device. In other words, the short-circuit capacity may be lowered in a semiconductor device having the FS layer.

According to an aspect of the present disclosure, a semiconductor device has a drift layer, a base layer, an emitter region, a gate insulation film, a gate electrode, a collector layer, a field stop layer, a first electrode and a second electrode. The drift layer has a first conductivity type. The base layer has a second conductivity type and is disposed on the drift layer. The emitter region has the first conductivity type, and is disposed at a surface layer portion of the base layer. The gate insulation film is disposed at a portion of the base layer between the drift layer and the emitter layer. The gate electrode is disposed on the gate insulation film. The collector layer has the second conductivity type, and is disposed at a location of the drift layer opposite to the base layer. The field stop layer has the first conductivity type and is disposed between the collector layer and the drift layer, and has a carrier concentration higher than a carrier concentration of the drift layer. The first electrode is electrically connected to the base layer and the emitter region. The second electrode is electrically connected to the collector layer. The field stop layer and the collector layer satisfy a relation of Y≥0.69X²+0.08X+0.86. X is in a unit of micrometer, and is denoted as a distance between a maximum peak position of the field stop layer at which the carrier concentration of the field stop layer is maximum and a maximum peak position of the collector layer at which the carrier concentration of the collector layer is maximum. Y is denoted as an impurity total amount ratio as a ratio of a dose amount in the collector layer to a dose amount in the field stop layer.

According to the above aspect of the present disclosure, it is possible to suppress an increase in the electric field strength at the lower electrode side, since the holes are easily injected at the time of short-circuit.

The following describes one or more embodiments of the present disclosure with reference to the drawings. In the following embodiments, the same or equivalent parts are denoted by the same reference numerals for description.

### First Embodiment

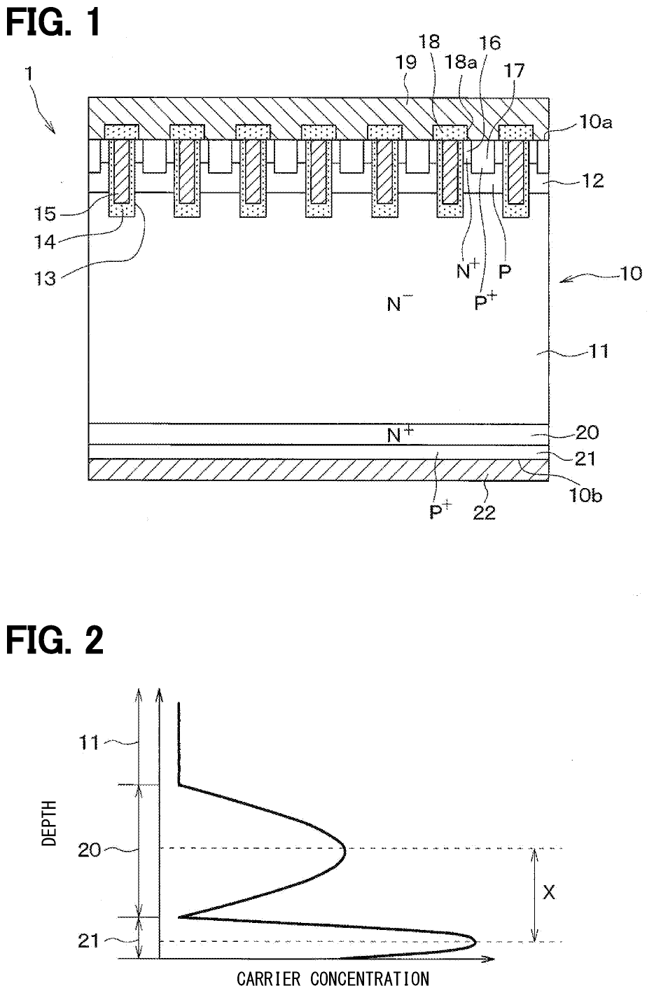

A semiconductor device according to a first embodiment will be described with reference to FIG. 1. A semiconductor device 1 according to the present embodiment may be adopted as, for example, a power-switching element used in power supply circuits such as inverters and DC/DC converters.

As illustrated in FIG. 1, the semiconductor device 1 includes an N⁻ type semiconductor substrate 10, which functions as a drift layer 11. A P type base layer 12 is formed on the drift layer 11 (that is, on a first surface 10a of the semiconductor substrate 10).

Multiple trenches 13 penetrating the base layer 12 to reach the drift layer 11 is formed at the semiconductor substrate 10, and the base layer 12 is partitioned by the multiple trenches 13. In the present embodiment, the trenches 13 are formed at regular intervals in a stripe manner along one direction included in a surface direction of the first surface 10a of the semiconductor substrate 10 (that is, a direction in a paper depth direction in FIG. 1).

In the trenches 13, a gate insulating film 14 formed to cover a wall surface of each of the trenches 13, and a gate electrode 15 formed on the gate insulating film 14 are embedded. As a result, a trench gate structure is formed. In the present embodiment, the gate insulation film 14 includes, for example, an oxide film, and the gate electrode 15 includes, for example, a doped polysilicon.

An N⁺ type emitter region 16 and a P⁺ type body region 17 are formed at a surface layer portion of the base layer 12. Specifically, the emitter region 16 is formed to have a carrier concentration higher than that of the drift layer 11, and formed to be terminated in the base layer 12 and in contact with a side surface of the trench 13. In contrast, the body region 17 is formed to have a carrier concentration higher than that of the base layer 12, and formed to be terminated in the base layer 12 like in the emitter region 16.

The emitter region 16 is extended in a bar shape along the longitudinal direction of the trench 13 in the region between the trenches 13 so as to be in contact with the side surface of the trench 13, and terminates at the inner side of a leading end of the trench 13. The body region 17 is sandwiched by two emitter regions 16 to be extended in a bar manner along the longitudinal direction of the trench 13 (that is, emitter region 16). The body region 17 according to the present embodiment is formed deeper than the emitter region 16 with respect to the first surface 10a of the semiconductor substrate 10.

An interlayer insulating film 18 including, for example, BPSG (abbreviation for Boro-phospho silicate glass) is formed on the first surface 10a of the semiconductor substrate 10, and a contact hole 18a is formed at the interlayer insulating film 18. The contact hole 18 causes a part of the emitter region 16 and a body region 17 to be exposed. An upper electrode 19 is electrically connected to the emitter region 16 and the body region 17 via the contact hole 18a, and is formed on the interlayer insulating film 18.

On the side of the drift layer 11 which is opposite from the base layer 12 (namely, on a second surface 10b of the semiconductor substrate 10), an N⁺ type FS layer 20 having a higher impurity concentration than that of the drift layer 11 is formed.

On the side opposite to the drift layer 11 across the FS layer 20, a P⁺ collector layer 21 included in the second surface 10b of the semiconductor substrate 10 is formed. A lower electrode 22 is formed on the collector layer 21 (in other words, on the second surface of the semiconductor substrate 10). The lower electrode 22 is to be electrically connected to the collector layer 21.

The FS layer 20 and the collector layer 21 in the present embodiment are formed through thermal treatment after ion implantation of impurities from the second surface 10b side of the semiconductor substrate 10. Therefore, each of the FS layer 20 and the collector layer 21 has a normal distribution of carrier concentration as illustrated in FIG. 2. In this situation, since the carrier concentration has a distribution with one peak, this peak is the maximum peak. In the present embodiment, the distance X between the maximum peak position of the carrier concentration of the FS layer 20 and the maximum peak position of the carrier concentration of the collector layer 21 is defined. In the following, the distance X between the maximum peak position of the carrier concentration of the FS layer 20 and the maximum peak position of the carrier concentration of the collector layer 21 may also be referred to as a peak-to-peak distance X between the FS layer 20 and the collector 21.

The configuration of the semiconductor device according to the present embodiment has been described above. In the present embodiment, N⁻ type, N type, and N⁺ type correspond to the first conductivity type, and P type and P⁺ type corresponds to the second conductivity type. In the present embodiment, the upper electrode 19 corresponds to a first electrode, and the lower electrode 22 corresponds to a second electrode. In the present embodiment, the semiconductor substrate 10 includes the collector layer 21, the FS layer 20, the drift layer 11, the base layer 12, the emitter region 17 and the contact region 18.

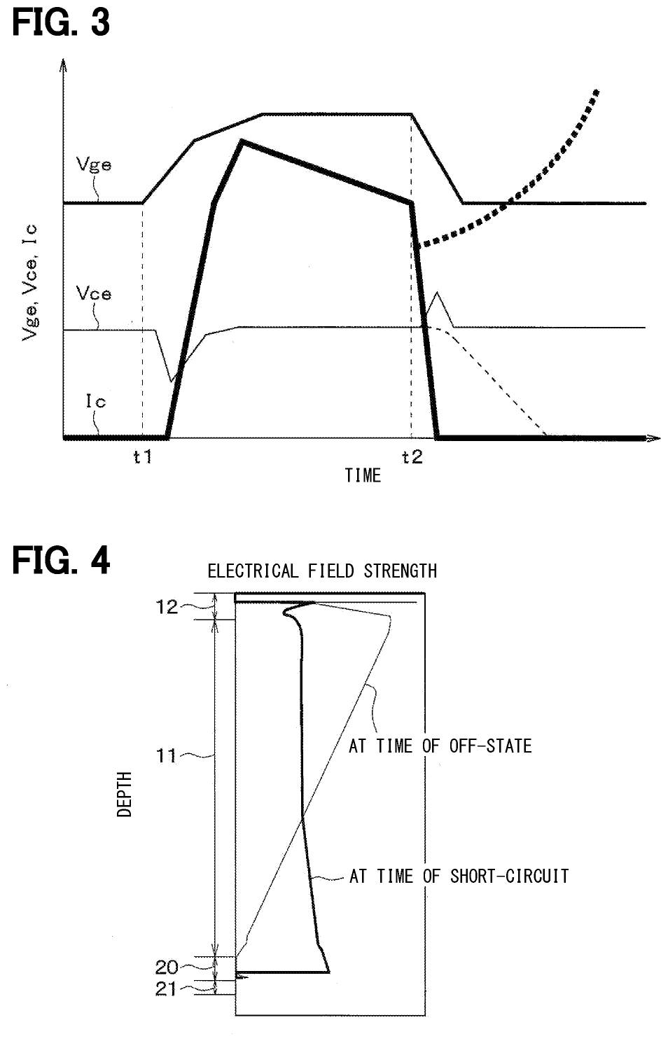

The following describes the operation of such a semiconductor device 1 with reference to FIG. 3.

For the semiconductor device 1 to be turned to an ON-state in which a current flows, a voltage larger than or equal to a predetermined threshold value is applied to the gate electrode 15 at time t1, in a situation where a voltage lower than the voltage of the lower electrode 22 is applied to the upper electrode 19. In the semiconductor device 1, a gate-emitter voltage Vge rises, and an N type inversion layer (that is, a channel) is formed in a portion of the base layer 12 in contact with the trench 13. Electrons are supplied to the drift layer 11 from the emitter region 16 through the inversion layer, and holes are supplied to the drift layer 11 from the collector layer 21, and a resistance value of the drift layer is reduced by a conductivity modulation, and the semiconductor device 1 is turned to the ON-state. In other words, the collector-emitter Vce drops and the current Ic flows through the semiconductor device 1. The voltage equal to or higher than a predetermined threshold value is a voltage that causes the gate-emitter voltage Vge to be higher than the threshold voltage Vth of the MOS gate.

In a situation where the voltage applied to the gate electrode 15 is stopped at the time t2, the gate-emitter voltage Vge drops and the inversion layer disappears so that the semiconductor device 1 is turned to an OFF-state. In other words, the semiconductor device 1 is turned to the OFF-state by decreasing the current Ic. In a situation where the semiconductor device 1 has a short-circuit, the current Ic rises in a rapid rate while the collector-emitter voltage Vce drops in a rapid rate, as illustrated by a dotted line in FIG. 3.

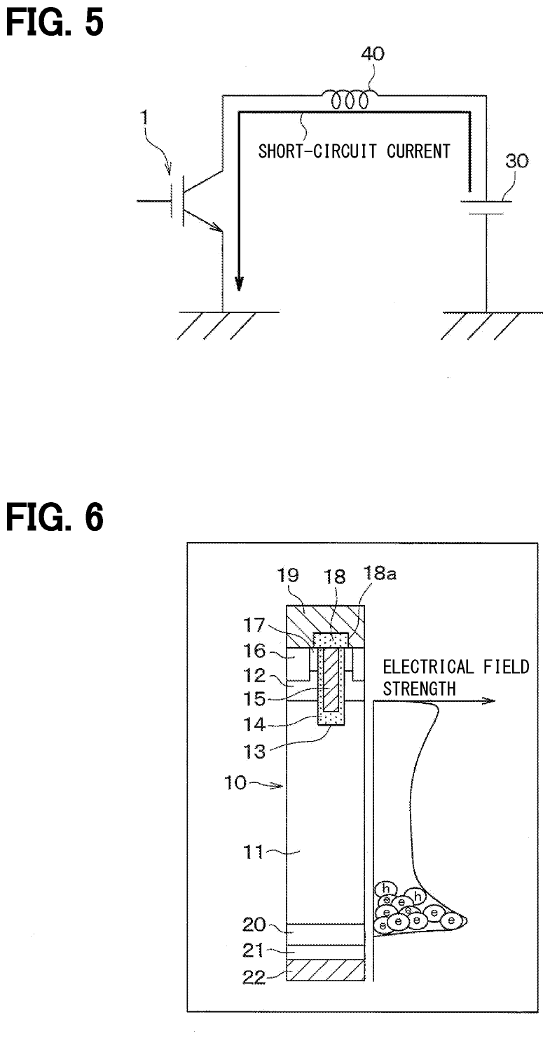

The following describes the electrical field strength of the semiconductor device 1 at the time of short-circuit with reference to FIG. 4. FIG. 4 illustrates a simulation result when a short-circuit evaluation is executed in a situation where the semiconductor device 1 is connected to a power supply 30 through a coil 40 as illustrated in FIG. 5. The FS layer 20 has a dose amount of 2.0×10¹² cm⁻², and the collector layer 21 has a dose amount of 3.56×10¹² cm⁻². FIG. 4 illustrates a simulation result in a situation where the peak-to-peak distance X between the FS layer 20 and the collector layer 21 is set to 1.5 μm.

As illustrated in FIG. 4, the electrical field strength of the semiconductor device 1 at the OFF-state has a peak in a vicinity of the junction between the base layer 12 and the drift layer 11, and gradually drops towards the collector layer 21 side. On the other hand, the electrical field strength of the semiconductor device 1 at the time of short-circuit has a peak in the FS layer 20 closer to the lower electrode 22 than the vicinity of the junction between the base layer 12 and the drift layer 11. The generation of the peak of the electrical field strength in the FS layer 20 at the time of short-circuit is caused by electrons at an excessive state and holes at a deficient state as illustrated in FIG. 6. The holes are injected in a portion where the end portion of the FS layer 20 at the lower electrode 22 side. In a situation where the peak of the electrical field strength occurs at a location closer to the lower electrode 22, it is likely that the breakdown of the semiconductor device 1 occurs with the generation of avalanche breakdown. In FIG. 6, holes are indicated by “h”, and electrons are indicated by “e”.

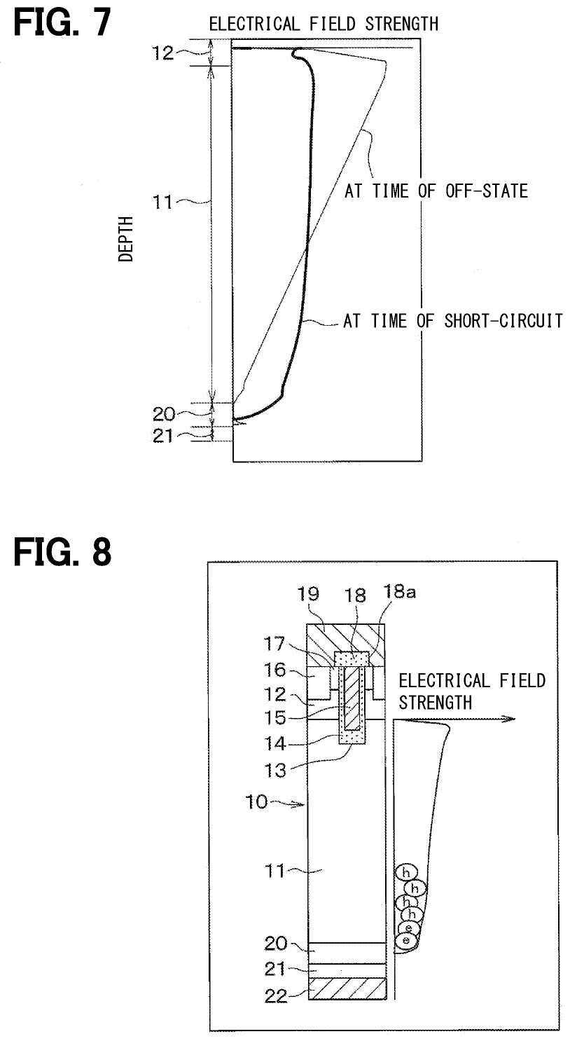

The inventors in the present application consider that it is unlikely to have the peak of the electrical field strength at a location closer to the lower electrode 22 by increasing the holes injected to a position of the FS layer 20 where the peak of the electrical field strength may be obtained and moderating the excessive state of the electrons. The inventors in the present application perform the identical simulation by increasing the carrier concentration of the collector layer 21 to increase the holes, which is to be injected to the position of the FS layer 20 where the peak of the electrical field strength may be obtained, and obtains the results shown in FIG. 7. The FS layer 20 has a dose amount of 2.0×10¹² cm⁻², and the collector layer 21 has a dose amount of 1.56×10¹² cm⁻². FIG. 7 illustrates a simulation result in a situation where the peak-to-peak distance X between the FS layer 20 and the collector layer 21 is set to 1.5 μm.

As illustrated in FIG. 7, even though the collector layer 21 has a high carrier concentration, the electrical field strength of the semiconductor device 1 at the OFF-state hardly changes. On the other hand, it is confirmed that the electrical field strength of the semiconductor device 1 at the time of short-circuit has a peak in the vicinity of the junction between the base layer 12 and the drift layer 11, without having the peak in the FS layer 20. The reason why the peak of the electrical field strength is difficult to occur in the FS layer 20 is that, as illustrated in FIG. 8, as the carrier concentration of the collector layer 21 is raised, the number of holes to be injected into a position of the FS layer 20, where the peak of the electrical field strength is likely to be formed, increases, and the excessive state of the number of electrons is moderated. In FIG. 8, holes are indicated by “h”, and electrons are indicated by “e”.

For causing the peak of the electrical field strength hardly to occur at a location closer to the lower electrode 22, the number of holes to be injected to a position of the FS layer 20, where the peak of the electrical field strength is likely to be formed, may be increased. The position of the FS layer 20 where the peak of the electrical field strength is likely to form at the time of short-circuit depends on the carrier concentration of the FS layer 20 and the maximum peak position of the carrier concentration of the FS layer 20. Further, the amount of holes injected into the position of the FS layer 20, where the peak of the electrical field strength is likely to be formed, depends on the carrier concentration of the collector layer 21 and the peak-to-peak distance X between the FS layer 20 and the collector layer 21.

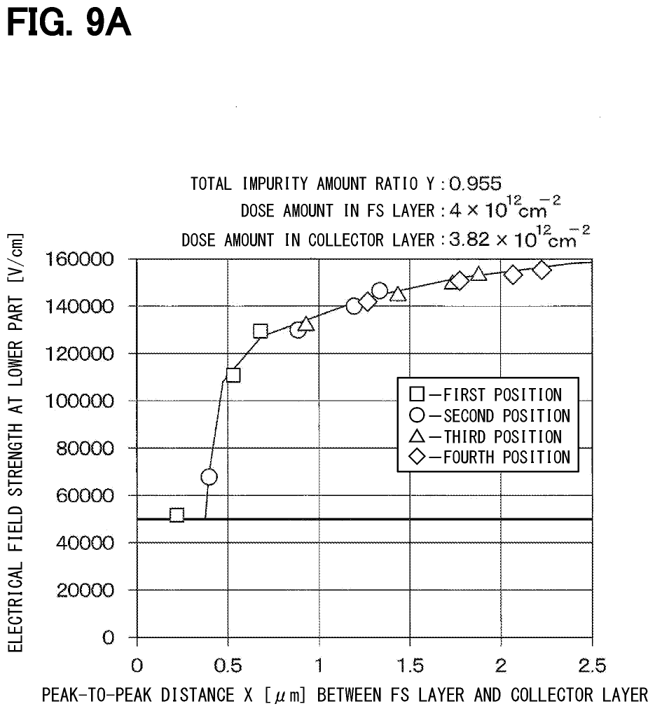

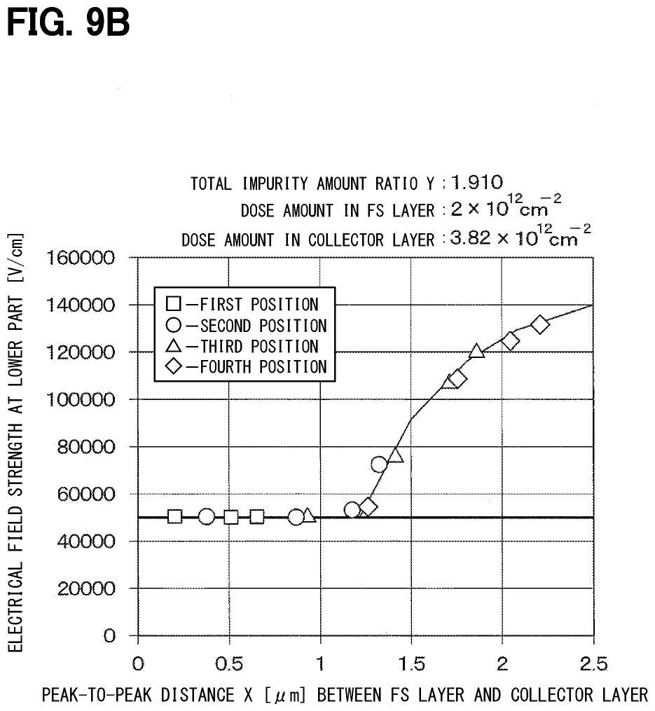

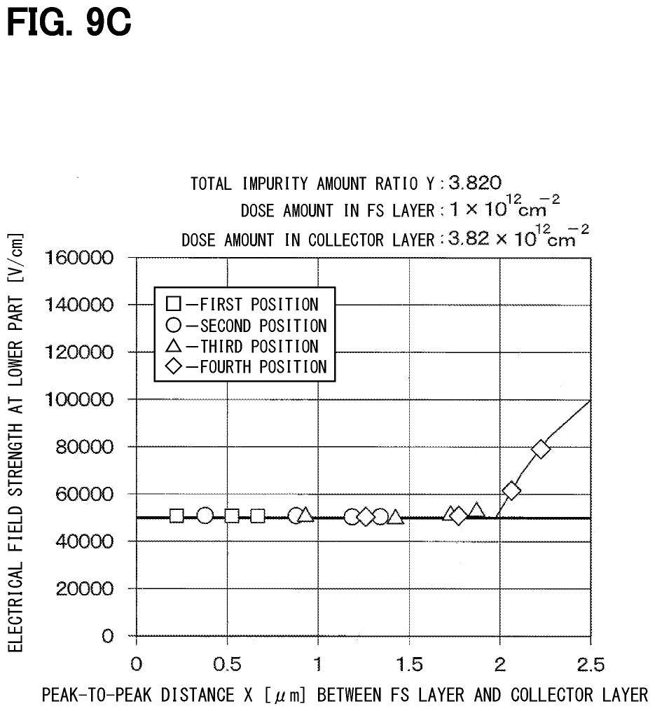

Therefore, the inventors in the present application have further been conducting a detailed study on the carrier concentration of the FS layer 20, the carrier concentration of the collector layer 21, and the peak-to-peak distance X between the FS layer 20 and the collector layer 21. In other words, the inventors in the present application have further been conducting a detailed study on the dose amount in the FS layer 20, the dose amount in the collector layer 21, and the peak-to-peak distance X between the FS layer 20 and the collector layer 21. Subsequently, the inventors in the present application obtained the simulation results shown in FIGS. 9A to 9C.

FIGS. 9A to 9C respectively illustrate a situation that the dose amount in the collector layer 21 is constant at 3.82×10¹² cm⁻², and the dose amount in the FS layer 20 is varied. In other words, FIGS. 9A to 9C respectively illustrate that the carrier concentration of the collector layer 21 is set to be constant while the carrier concentration of the FS layer 20 is varied. FIGS. 9A to 9C respectively illustrate the electrical field strength at the lower electrode 22 side at the time of short-circuit as a simulation result, in a situation where the power supply voltage is set to 757 V, and the voltage applied to the gate electrode 15 is set to 16 V. In the following, the electrical field strength at a location closer to the lower electrode 22 at the time of short-circuit is simply referred to as “electrical field strength at the lower part”.

FIGS. 9A to 9C respectively illustrate that the first to fourth positions correspondingly indicate the positions of the peak of the carrier concentration at the FS layer 20. The first position is the closest to the second surface 10b, and the second to fourth positions are positions deviated from the second surface 10b in order. The total impurity amount ratio Y in each of FIGS. 9A to 9c is a ratio of the dose amount in the collector layer 21 to the dose amount in the FS layer 20. However, the carrier concentration of the FS layer 20 depends on the dose amount in the FS layer 20, and the carrier concentration of the collector layer 21 depends on the dose amount in the collector layer 21. Therefore, the total impurity amount ratio Y may also be the ratio of the carrier concentration of the collector layer 21 to the carrier concentration of the FS layer 20.

As illustrated in FIGS. 9A to 9C, it is confirmed that the approximate curves derived from respective plots at the first to fourth positions are identical. It is confirmed that the electrical field strength at the lower part does not depend on the peak position of the carrier concentration of the FS layer 20, but depends on the peak-to-peak distance X between the FS layer 20 and the collector layer 21. The electrical field strength at the lower part is identical even though the peak positions of the carrier concentration of the FS layer 20 are different, as long as the peak-to-peak distances X between the FS layer 20 and the collector layer 21 are identical.

As illustrated in FIG. 9A, in a situation where the dose amount in the FS layer 20 is 4×10¹² cm⁻², in other words, the total impurity amount ratio Y is 0.955, the electrical field strength starts to rise as the peak-to-peak distance X reaches 0.4 μm or more in the semiconductor device 1. The start of a rise in the electrical field strength at the lower part refers to a situation where the avalanche breakdown easily occurs at the time of short-circuit.

As illustrated in FIG. 9B, in a situation where the dose amount in the FS layer 20 is 2×10¹² cm⁻², in other words, the total impurity amount ratio Y is 1.910, the electrical field strength starts to rise as the peak-to-peak distance X reaches 1.2 μm or more in the semiconductor device 1.

As illustrated in FIG. 9C, in a situation where the dose amount in the FS layer 20 is 1×10¹² cm⁻², in other words, the total impurity amount ratio Y is 3.820, the electrical field strength starts to rise as the peak-to-peak distance X reaches 1.8 μm or more in the semiconductor device 1.

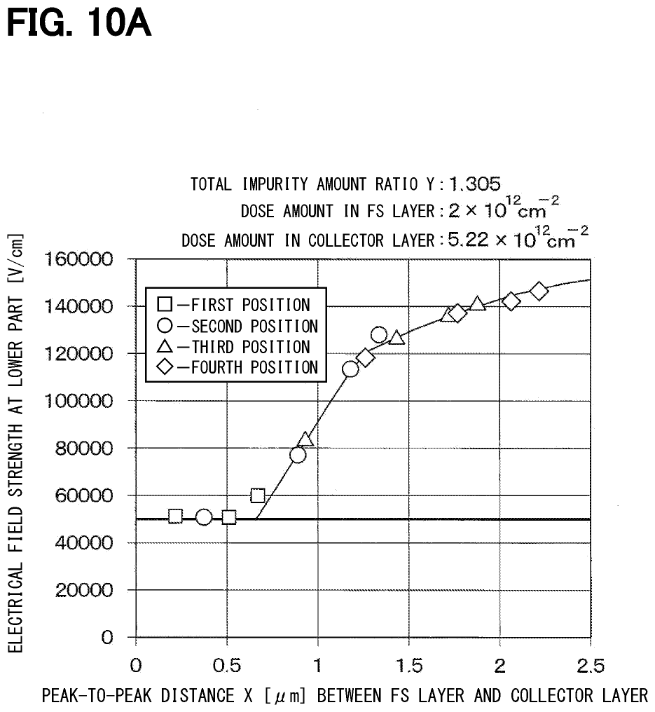

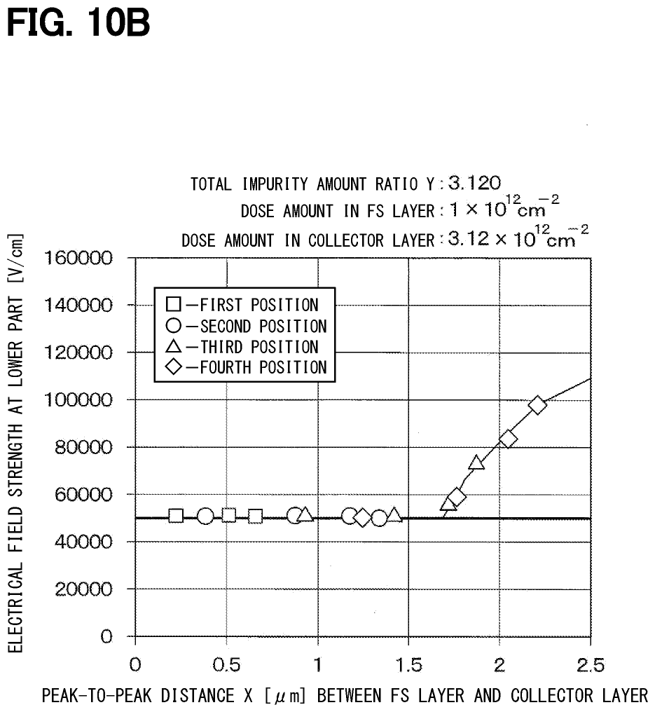

The inventors in the present application changed the dose amount in the FS layer 20 and the dose amount in the collector layer 21 and performed the identical simulation, and then obtained the results shown in FIGS. 10A and 10B.

As illustrated in FIG. 10A, in a situation where the dose amount in the FS layer 20 is 2×10¹² cm⁻², and the dose amount in the collector layer 21 is 5.22×10¹² cm⁻², the electrical field strength starts rising as the peak-to-peak distance X reaches 0.7 μm or more in the semiconductor device 1. In the semiconductor device 1, in a situation where the total impurity amount ratio Y is 1.305, the electrical field strength starts to rise as the peak-to-peak distance X reaches 0.7 μm or more. As illustrated in FIG. 10B, in a situation where the dose amount in the FS layer 20 is 1×10¹² cm⁻², and the dose amount in the collector layer 21 is 3.12×10¹² cm⁻², the electrical field strength at the lower part starts rising as the peak-to-peak distance X reaches 1.7 μm or more in the semiconductor device 1. In the semiconductor device 1, in a situation where the total impurity amount ratio Y is 3.120, the electrical field strength starts rising as the peak-to-peak distance X reaches 1.7 μm or more.

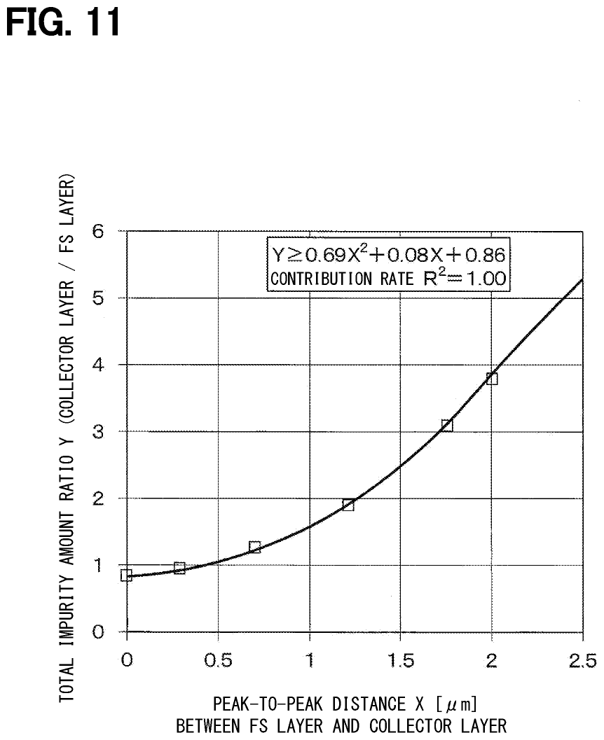

It is confirmed that the electrical field strength at the lower part depends on the total impurity amount ratio Y and the peak-to-peak distance X between the FS layer 20 and the collector layer 21. The relationship between the total impurity amount ratio Y and the peak-to-peak distance X between the FS layer 20 and the collector layer 21 is illustrated in FIG. 11, by adopting FIGS. 9A to 9C and 10B. FIG. 11 is a plot of the peak-to-peak distance X between the FS layer 20 and the collector layer 21 in relation to each of the total impurity amount ratios Y respectively in FIGS. 9A to 9C, FIG. 10A and FIG. 10B as the electrical field strength at the lower part starts rising.

As illustrated in FIG. 11, it is confirmed that it is possible to suppress an increase in the electrical field strength at the lower part in a condition that the semiconductor device 1 satisfies the relation Y≥0.69X²+0.08X+0.86, where X represents the peak-to-peak distance between the FS layer 20 and the collector 21 and is in a unit of μm (micrometer), and Y represents the impurity total amount ratio. Therefore, in the present embodiment, the FS layer 20 and the collector layer 21 are formed so as to satisfy the relation Y≥0.69X²+0.08X+0.86. As a result, it is possible to suppress an increase in the electrical field strength at the lower part while improving the short-circuit capacity.

It is possible to improve the short-circuit capacity in a situation where the FS layer 20 and the collector layer 21 are formed to satisfy the relation Y≥0.69X²+0.08X+0.86. However, it is possible that the switching speed may be lowered through a tail current in a situation where the total impurity amount ratio Y is raised too high. The total impurity amount ratio Y may be designed as appropriate according to the application or purpose. For instance, in a situation where the switching speed is emphasized, it may be set to a value closer to a value set by the relation 0.69X²+0.08X+0.86. According to the above configuration, the short-circuit capacity can be improved while suppressing a decrease in the switching speed.

In a situation of selecting the peak-to-peak distance X between the FS layer 20 and the collector layer 21 and the total impurity amount ratio Y, the collector layer 21 may be set such that the carrier concentration at a portion in the second surface 10b is 1×10¹⁶ cm⁻³ or more. As a result, the collector layer 21 may be brought into ohmic contact with the lower electrode 22.

Therefore, in the present embodiment, the FS layer 20 and the collector layer 21 are formed so as to satisfy the relation Y≥0.69X²+0.08X+0.86. For the semiconductor device 1 in the present embodiment, it is possible to improve the short-circuit capacity while suppressing an increase in the electrical field strength at the time of the short-circuit.

### Second Embodiment

The following describes a second embodiment. The second embodiment is different from the first embodiment in that the distribution of the carrier concentration in the collector layer 21 is modified. The remaining configuration is similar to that according to the first embodiment and will thus not be described repeatedly.

The semiconductor device 1 according to the present embodiment is essentially configured similarly to the first embodiment. In the present embodiment, the collector layer 21 has a carrier concentration having multiple peaks as illustrated in FIG. 12. In a situation where the stacking direction of the collector layer 21 and the FS layer 20 is defined as a thickness direction, the collector layer 21 may be formed such that the maximum peak position of the carrier concentration is located at a location closer to the drift layer 11 than the center C1 in the thickness direction. The collector layer 21 is formed such that the auxiliary peak smaller than the maximum peak in the carrier concentration is located at a location closer to the second surface 10b than the center C1 in the thickness direction. In other words, the collector layer 21 may be formed such that the distribution of the carrier concentration is asymmetric with respect to the center C1 in the thickness direction.

Such a collector layer 21 is formed by, for example, performing multiple times of ion implantations for changing an acceleration voltage.

In the present embodiment, the collector layer 21 is formed such that the maximum peak position of the carrier concentration is located at a location closer to the drift layer 11 than the center C1. Therefore, it is possible to easily shorten the peak-to-peak distance between the FS layer 20 and the collector layer 21 for the semiconductor device 1. For example, as compared with a situation where the maximum peak position of the carrier concentration in the collector layer 21 is located at a location closer to the second surface 10b side than the center C1, it is possible to easily increase the number of holes to be injected to a position of the FS layer 20 where the peak of the electrical field strength is easily formed while improving the short-circuit capacity.

The collector layer 21 is formed to have the auxiliary peak at a location closer to the second surface 10b than the center C1. Even though the collector layer 21 is formed deeper from the second surface 10b, the carrier concentration at a portion included in the second surface 10b at the collector layer 21 may be easily set to 1.0×10¹⁶ cm⁻³ or more. Since the collector layer 21 may be easily formed to be deeper from the second surface 10b, the boundary surface between the FS layer 20 and the collector layer 21 may be easily formed at a position deeper from the second surface 10b. In other words, it is possible to easily lengthen the spacing between the FS layer 20 and the second surface 10b.

The semiconductor device 1 as described above is manufactured by performing a predetermined manufacturing process. In the manufacturing process, for example, the thickness of the semiconductor substrate 10 is reduced by grinding or the like from the second surface 10b side and transported. In this situation, a scratch may reach the second surface 10b of the semiconductor substrate 10. In a situation where the FS layer 20 is formed, if a scratch reaches the FS layer 20 or if a scratch reaches a portion of forming the FS layer 20 before the formation of the FS layer 20, the withstand voltage of the semiconductor device 1 may change due to the scratch. That is, the characteristics of the semiconductor device 1 may vary. In particular, in a situation where the scratch reaches a portion where the end portion of the depletion layer is located, the characteristics of the semiconductor device 1 is significantly varied.

In the present embodiment, it is possible to easily lengthen the spacing between the FS layer 20 and the second surface 10b by forming the collector layer 21 as described above. Therefore, the semiconductor device 1 according to the present embodiment may be configured so that the scratch does not easily reach the FS layer 20. It is possible to suppress a change in the characteristics of the semiconductor device 1 in the present embodiment. In other words, it is possible to improve quality efficiency for the semiconductor device 1 in the present embodiment.

### Third Embodiment

The following describes a third embodiment. The third embodiment is different from the first embodiment in that the distribution of the carrier concentration in the FS layer 20 is changed. The remaining configuration is similar to that according to the first embodiment and will thus not be described repeatedly.

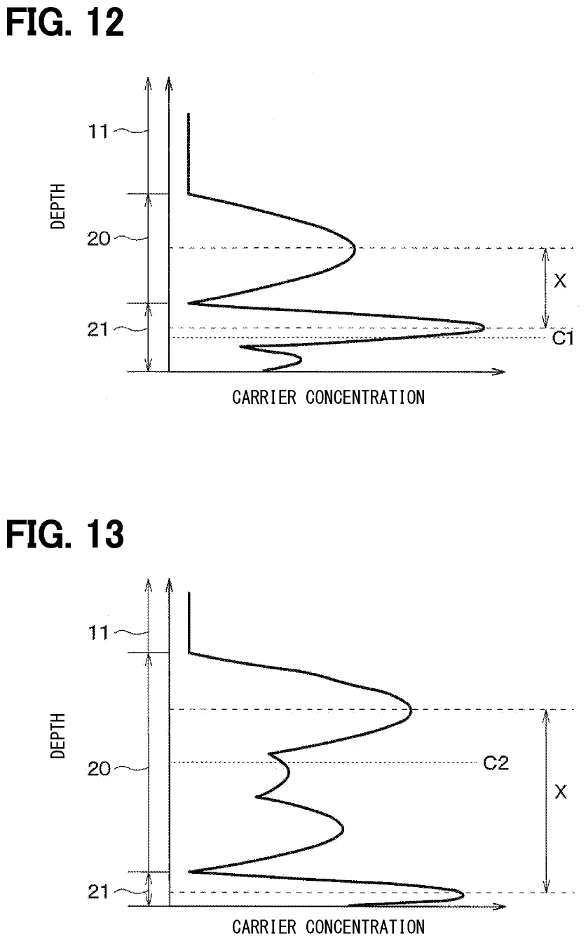

The semiconductor device 1 according to the present embodiment is basically configured similarly to the first embodiment. In the present embodiment, the FS layer 20 has a carrier concentration having multiple peaks as illustrated in FIG. 13. The collector layer 20 is formed such that the maximum peak position of the carrier concentration is located closer to the drift layer 11 than the center C2 in the thickness direction.

Therefore, the FS layer 20 has the maximum peak position located at a location closer to the drift layer 11 than the center C2 of the FS layer 20. For example, in comparison with a situation where the maximum peak is located at the center C2 of the FS layer 20, it is possible to locate the end portion of the depletion layer closer to the drift layer 11. Therefore, it is difficult for the scratch to reach a position where the end portion of the depletion layer is formed, and it is possible to suppress a change in the characteristics of the semiconductor device 1.

### Fourth Embodiment

The following describes a fourth embodiment. The fourth embodiment is different from the first embodiment in that the distribution of the carrier concentration in the FS layer 20 is changed. The remaining configuration is similar to that according to the first embodiment and will thus not be described repeatedly.

The semiconductor device 1 according to the present embodiment is basically configured similarly to the first embodiment. In the present embodiment, the FS layer 20 has a carrier concentration having multiple peaks as illustrated in FIG. 14. The FS layer 20 is formed such that the maximum peak position of the carrier concentration is located closer to the drift layer 11 than the center C2 in the thickness direction.

Therefore, the FS layer 20 has the maximum peak position located closer to the collector layer 21 than the center C2 of the FS layer 20. In comparison with a situation where the maximum peak position locates at the center C2 of the FS layer 20, it is possible to easily shorten the peak-to-peak distance X between the FS layer 20 and the collector layer 21. Therefore, it is possible to improve the short-circuit capacity.

### Other Embodiments

Although the present disclosure has been described in accordance with the embodiments, it is understood that the present disclosure is not limited to such embodiments or structures. The present disclosure encompasses various modifications and variations within the scope of equivalents. Furthermore, various combinations and aspects, and other combination and aspect including only one element, more than one element or less than one element, are also within the sprit and scope of the present disclosure.

For example, in each of the above embodiments, the first conductivity type may be P type, and the second conductivity type may be N type.

Each of the above embodiments may be applied to an RC-IGBT having an N type cathode layer at a location closer to the second surface 10b of the semiconductor substrate 10. RC is an abbreviation for “Reverse-Conducting”.

In each of the above embodiments, the trench 13 may not be formed, and the gate electrode 15 may be formed on the first surface 10a of the semiconductor substrate 10. Each of the above embodiments may also be applied to a planar type semiconductor device 1.

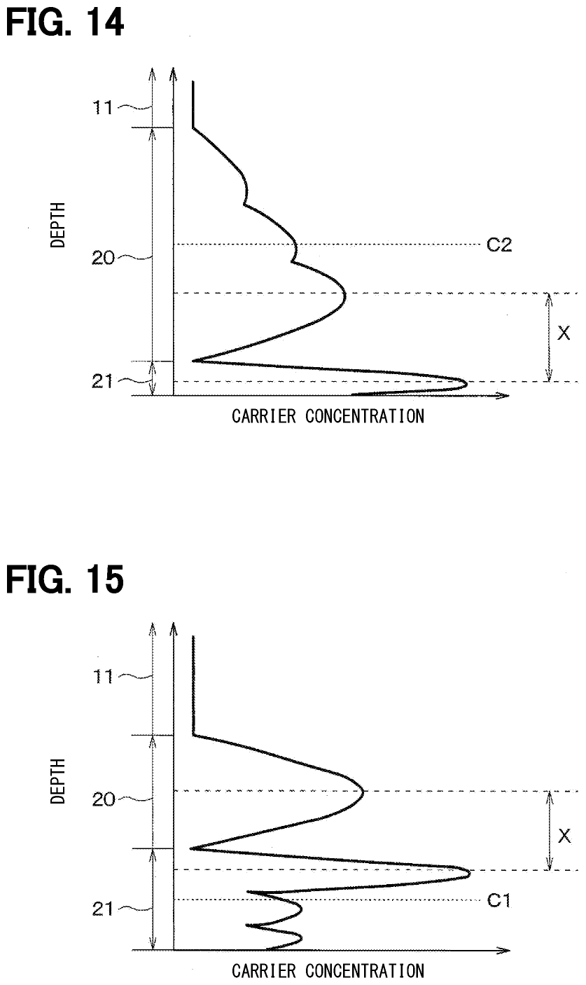

In the second embodiment, as illustrated in FIG. 15, the collector layer 21 may have multiple auxiliary peaks, which are smaller than the maximum peak, in the carrier concentration distribution. In the second embodiment, it is not necessary for the collector layer 21 to have one or more auxiliary peaks.

Further, the above embodiments may be combined together as appropriate. For example, the second embodiment may be combined with the third and fourth embodiments so that the carrier concentration of the collector layer 21 may have multiple peaks.

What is claimed is:

1. A semiconductor device comprising:
a drift layer of a first conductivity type;
a base layer of a second conductivity type disposed on the drift layer;
an emitter region of the first conductivity type disposed at a surface layer portion of the base layer;
a gate insulation film disposed at a portion of the base layer between the drift layer and the emitter layer;
a gate electrode disposed on the gate insulation film;
a collector layer of the second conductivity type disposed at a location of the drift layer opposite to the base layer;
a field stop layer of the first conductivity type disposed between the collector layer and the drift layer, and having a carrier concentration higher than a carrier concentration of the drift layer;
a first electrode electrically connected to the base layer and the emitter region; and
a second electrode electrically connected to the collector layer,
wherein the field stop layer and the collector layer satisfy a relation of Y≥0.69X²+0.08X+0.86,
wherein X is in a unit of micrometer, and is denoted as a distance between a maximum peak position of the field stop layer at which the carrier concentration is maximum in the field stop layer and a maximum peak position of the collector layer at which the carrier concentration is maximum in the collector layer,
wherein Y is denoted as an impurity total amount ratio as a ratio of a dose amount in the collector layer to a dose amount in the field stop layer, and
wherein the maximum peak position of the collector layer is disposed closer to the drift layer from a center of the collector layer in a stacking direction of the collector layer and the field stop layer.

2. The semiconductor device according to claim 1,
wherein the carrier concentration of the collector layer has a plurality of peaks, and
wherein the plurality of peaks include an auxiliary peak, which is smaller than a maximum peak of the carrier concentration of the collector layer, closer to a position of the collector layer opposite to the drift layer from the center of the collector layer.

3. The semiconductor device according to claim 1,
wherein the maximum peak position of the field stop layer at which the carrier concentration is maximum in the field stop layer is disposed closer to the drift layer from a center of the field stop layer in the stacking direction of the collector layer and the field stop layer.

4. The semiconductor device according to claim 1,
wherein the maximum peak position of the field stop layer at which the carrier concentration is maximum in the field stop layer is disposed closer to the collector layer from a center of the field stop layer in the stacking direction of the collector layer and the field stop layer.
